(19) United States
(12) Patent Application Publication
(10) Pub. No.: US 2021/0319150 A1
(43) Pub. Date: Oct. 14, 2021

(54) INSTRUCTION AUTHORING TOOL

(71) Applicant: THE BOEING COMPANY, Chicago, IL (US)

(72) Inventors: Cristina Boyer, Edwardsville, IL (US); Clifford B. Sowadski, Eureka, MO (US)

(73) Assignee: The Boeing Company

(21) Appl. No.: 16/845,241

(22) Filed: Apr. 10, 2020

(51) Int. Cl. G06F 30/20; G06F 16/22; G06F 16/9035; G06F 16/9032; G06F 40/205

(52) U.S. Cl. CPC G06F 30/20; G06F 16/221; G06F 40/205; G06F 16/9035; G06F 16/90332; G06F 16/2282

(57) ABSTRACT

A method includes obtaining, at one or more processors of an instruction authoring tool, a lesson description document for a simulation scenario including a plurality of simulation events. The method also includes parsing, by the one or more processors, the lesson description document to generate a simulation data model. The simulation data model identifies a sequence of the plurality of simulation events and identifiers of simulation output files to support the simulation scenario. The method further includes generating, by the one or more processors, executable code to implement the simulation scenario based on the simulation data model and the simulation output files.

### FIELD OF THE DISCLOSURE

The present disclosure is generally related to systems and methods for authoring instructional simulations.

### BACKGROUND

Simulation-based training can be very useful to help students develop and practice skills. However, it can be challenging to prepare lessons in a complex simulation environment. For example, it is often the case that professional trainers have the expertise required for lesson planning but not the expertise required for simulation programming Likewise, a programmer may have the expertise required for simulation programming but not the expertise required for lesson planning As a result, it is not uncommon for teams of people to work through multiple iterations in order to program a simulation-based training lesson.

### SUMMARY

In a particular implementation, a computing device includes one or more processors and one or more memory devices storing instructions. The instructions are executable by the one or more processors to cause the one or more processors to initiate, perform, or control operations including obtaining a lesson description document for a simulation scenario including a plurality of simulation events. The operations also include parsing the lesson description document to generate a simulation data model. The simulation data model identifies a sequence of the plurality of simulation events and identifiers of simulation output files to support the simulation scenario. The operations further include generating executable code to implement the simulation scenario based on the simulation data model and the simulation output files.

In another particular implementation, a method includes obtaining, at one or more processors of an instruction authoring tool, a lesson description document for a simulation scenario including a plurality of simulation events. The method also includes parsing, by the one or more processors, the lesson description document to generate a simulation data model. The simulation data model identifies a sequence of the plurality of simulation events and identifiers of simulation output files to support the simulation scenario. The method further includes generating, by the one or more processors, executable code to implement the simulation scenario based on the simulation data model and the simulation output files.

In another particular implementation, a computer-readable storage device stores instructions that are executable by one or more processors to cause the one or more processors to initiate, perform, or control operations. The operations include obtaining a lesson description document for a simulation scenario including a plurality of simulation events. The operations also include parsing the lesson description document to generate a simulation data model identifying a sequence of the plurality of simulation events and identifiers of simulation output files to support the simulation scenario. The operations further include generating executable code to implement the simulation scenario based on the simulation data model and the simulation output files.

The features, functions, and advantages described herein can be achieved independently in various implementations or may be combined in yet other implementations, further details of which can be found with reference to the following description and drawings.

### BRIEF DESCRIPTION OF THE DRAWINGS

FIG. 1 is a block diagram that illustrates a system including an instruction authoring tool according to a particular implementation.

FIG. 2 is a diagram illustrating aspects of a lesson description document that can be used by the instruction authoring tool of FIG. 1 according to a particular implementation.

FIG. 3 is a diagram illustrating a first display screen including particular aspects of a graphical representation of a simulation data model produced by the instruction authoring tool of FIG. 1 according to a particular implementation.

FIG. 4 is a diagram illustrating a second display screen including particular aspects of a graphical representation of a simulation data model produced by the instruction authoring tool of FIG. 1 according to a particular implementation.

FIG. 5 is a diagram illustrating a third display screen including particular aspects of a graphical representation of a simulation data model produced by the instruction authoring tool of FIG. 1 according to a particular implementation.

FIG. 6 is a diagram illustrating a fourth display screen including particular aspects of a graphical representation of a simulation data model produced by the instruction authoring tool of FIG. 1 according to a particular implementation.

FIG. 7 is a flowchart of a particular implementation of a method of authoring an instructive simulation using the instruction authoring tool of FIG. 1.

FIG. 8 is a block diagram of a computing environment including a computing device configured to support aspects of computer-implemented methods and computer-executable program instructions (or code) according to the present disclosure.

### DETAILED DESCRIPTION

The figures and the following description illustrate specific exemplary aspects of an instruction authoring tool that provides an instructional designer a way to create an adaptive instructional lesson within a simulation training environment without writing any software code. The instructional designer can identify instructional events and link feedback, scoring of student responses to events, hints, etc. to the instructional events in a lesson description document. The lesson description document is a structured document that organizes the instructional design in one or more tables and is readily editable using familiar business office software. After the instructional designer completes the lesson description document, the instruction authoring tool maps the contents of the one or more tables into executable code segments and parameter values to generate code that can be executed by a simulation device to produce a simulation scenario. As a result, the instruction authoring tool reduces software coding requirements when authoring adaptive training within a simulation environment.

It will be appreciated that those skilled in the art will be able to devise various arrangements that, although not explicitly described or shown herein, embody the principles described herein and are included within the scope of the claims that follow this description. Furthermore, any examples described herein are intended to aid in understanding the principles of the disclosure and are to be construed as being without limitation. As a result, this disclosure is not limited to the specific embodiments or examples described below, but by the claims and their equivalents.

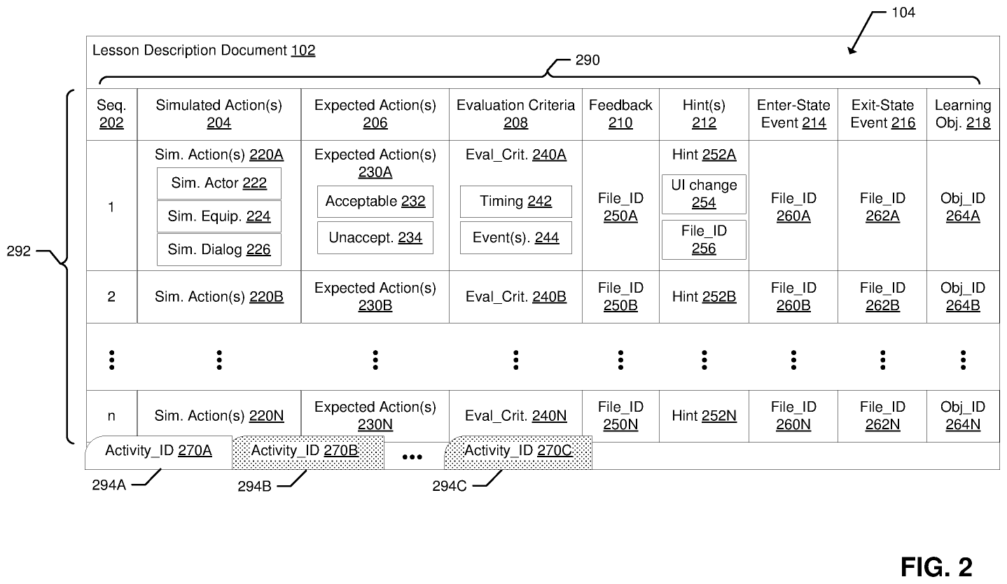

Particular implementations are described herein with reference to the drawings. In the description, common features are designated by common reference numbers throughout the drawings. In some drawings, multiple instances of a particular type of feature are used. Although these features are physically and/or logically distinct, the same reference number is used for each, and the different instances are distinguished by addition of a letter to the reference number. When the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 2, multiple examples of simulated actions are illustrated and associated with reference numbers 220A, 220B, and 220N. When referring to a particular one of these simulated actions, such as the simulated action 220A, the distinguishing letter “A” is used. However, when referring to any arbitrary one of these simulated actions or to these simulated actions as a group, the reference number 220 is used without a distinguishing letter.

As used herein, various terminology is used for the purpose of describing particular implementations only and is not intended to be limiting. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular unless aspects related to multiple of the features are being described.

The terms “comprise,” “comprises,” and “comprising” are used interchangeably with “include,” “includes,” or “including.” Additionally, the term “wherein” is used interchangeably with the term “where.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to a grouping of one or more elements, and the term “plurality” refers to multiple elements.

As used herein, “generating”, “calculating”, “using”, “selecting”, “accessing”, and “determining” are interchangeable unless context indicates otherwise. For example, “generating”, “calculating”, or “determining” a parameter (or a signal) can refer to actively generating, calculating, or determining the parameter (or the signal) or can refer to using, selecting, or accessing the parameter (or signal) that is already generated, such as by another component or device. As used herein, “coupled” can include “communicatively coupled,” “electrically coupled,” or “physically coupled,” and can also (or alternatively) include any combinations thereof. Two devices (or components) can be coupled (e.g., communicatively coupled, electrically coupled, or physically coupled) directly or indirectly via one or more other devices, components, wires, buses, networks (e.g., a wired network, a wireless network, or a combination thereof), etc. Two devices (or components) that are electrically coupled can be included in the same device or in different devices and can be connected via electronics, one or more connectors, or inductive coupling, as illustrative, non-limiting examples. In some implementations, two devices (or components) that are communicatively coupled, such as in electrical communication, can send and receive electrical signals (digital signals or analog signals) directly or indirectly, such as via one or more wires, buses, networks, etc. As used herein, “directly coupled” is used to describe two devices that are coupled (e.g., communicatively coupled, electrically coupled, or physically coupled) without intervening components.

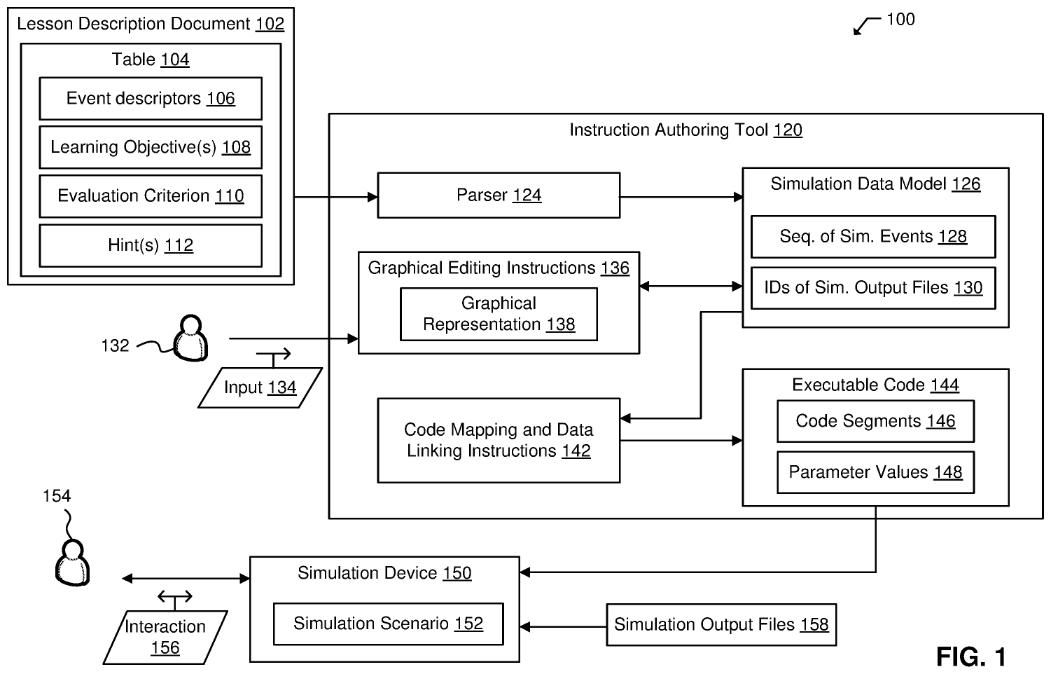

FIG. 1 is a block diagram that illustrates a system 100 that includes an instruction authoring tool 120 according to a particular implementation. In FIG. 1, the system 100 also includes a simulation device 150. In some implementations, the simulation device 150 is combined with the instruction authoring tool 120 in one or more other computing devices. In some implementations, the simulation device 150 includes other devices or components, such as a physical model of a system to be simulated (e.g., an aircraft cockpit model, an automobile model, a control system operator console model, etc.).

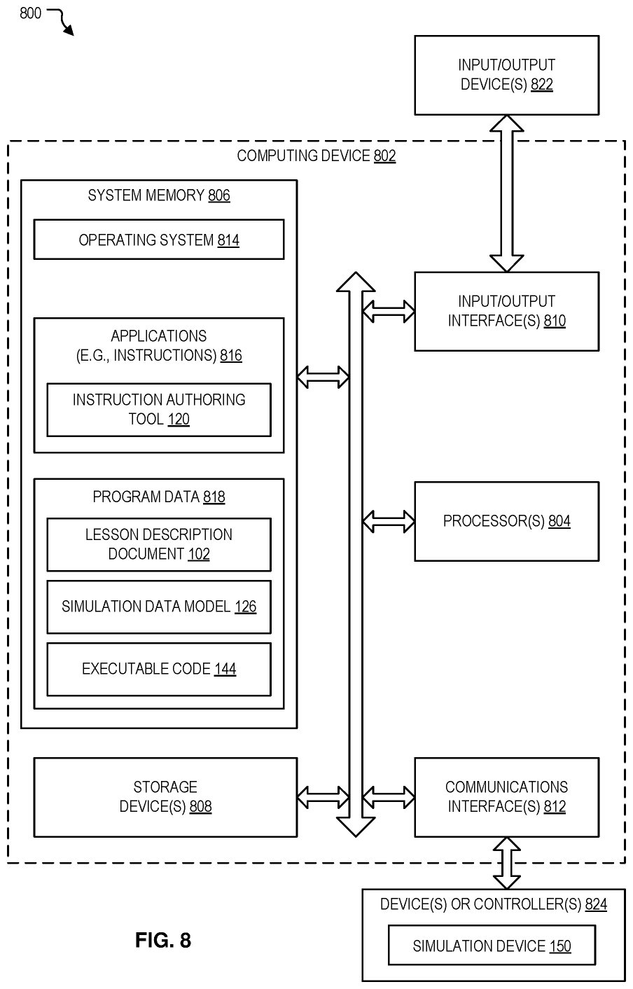

In a particular implementation, the instruction authoring tool 120 is software code that enables a computing device to operate as a special purpose computing device to generate executable code 144 based on a lesson description document 102. For example, the instruction authoring tool 120 and the simulation device 150 each include, are included within, or correspond to one or more computing devices, such as computing device 802 of FIG. 8. For example, the computing device(s) include one or more processors (e.g., processor(s) 804 of FIG. 8), one or more memory devices (e.g., system memory 806 and/or storage device(s) 808 of FIG. 8), and one or more interface devices (e.g., input/output interface(s) 810 and/or communications interface(s) 812 of FIG. 8). In this example, the processor(s) 804 are coupled to the memory device(s) and the interface device(s). The interfaces device(s) facilitate communications with other computing devices and with users. The memory device(s) include computer-readable media that stores instructions that are executable by the processor(s). The instructions are executable to initiate, perform or control operations to aid in generating code as part of a simulation-based training lesson, as described further below. The processor(s) can be implemented as a single processor or as multiple processors, such as in a multi-core configuration, a multi-processor configuration, a distributed computing configuration, a cloud computing configuration, or any combination thereof.

The instruction authoring tool 120 is configured to generate executable code 144 based on a lesson description document 102. The lesson description document 102 is a structured document that is readily modified without specialized computers programming skills or software. To illustrate, in a particular implementation, the lesson description document 102 is a data structure, such as a table 104 (e.g., a spreadsheet) that can be edited in a common desktop software environment. In contrast, the executable code 144 includes or corresponds to computer executable instructions, such as scripts, instructions in a high-level programming language, or binary instructions.

In FIG. 1, various aspects of the instruction authoring tool 120 are illustrated as functional blocks, such as a parser 124, graphical editing instructions 136, and code mapping and data linking instructions 142. The functional blocks are illustrated merely to facilitate description of various aspects of the instruction authoring tool 120 and its use. In other implementations, the instruction authoring tool 120 includes more, fewer, or different functional blocks, or is a monolithic instruction set (e.g., no distinct functional blocks).

The lesson description document 102 specifies or identifies a set of events to be performed as part of a simulation scenario 152. In some implementations, the lesson description document 102 includes one or more event descriptors 106 (describing events to be simulated), one or more learning objectives 108 for the simulation scenario 152, an evaluation criterion (or evaluation criteria) 110 for the simulation scenario 152, one or more hints 112 that can be provided during the simulation scenario 152, other aspects of the simulation scenario 152, or a combination thereof. FIG. 2 illustrates an example of the lesson description document 102.

The event descriptors 106 include names, file location pointers (e.g., links), other information descriptive of simulation events to be simulated in the simulation scenario 152, or a combination thereof. In a particular implementation, each simulation event includes or corresponds to an interaction 156 between a student 154 participating in the simulation scenario 152 and at least one of a simulated person, a simulated environment, or a simulated device. In this implementation, a person, an environment, or a device is simulated using one or more simulation output files 158, one or more code segments 146, or both. For example, in this implementation, a particular simulation output file 158 is an audio file that includes audio representing speech of a simulated person or sound output by a simulated device. As another example, a particular simulation output file 158 is a video file that includes animation or a three-dimensional representation of the simulated person, the simulated device, the simulated environment, or a combination thereof. The video file can also include audio. The simulation output files 158 are prepared by sound artists, videographers, animators, other types of graphic media artists, technicians, project personnel, media graphics programs, or combinations thereof. The simulation output files 158 provide content associated with the one or more learning objectives 108 to the student 154.

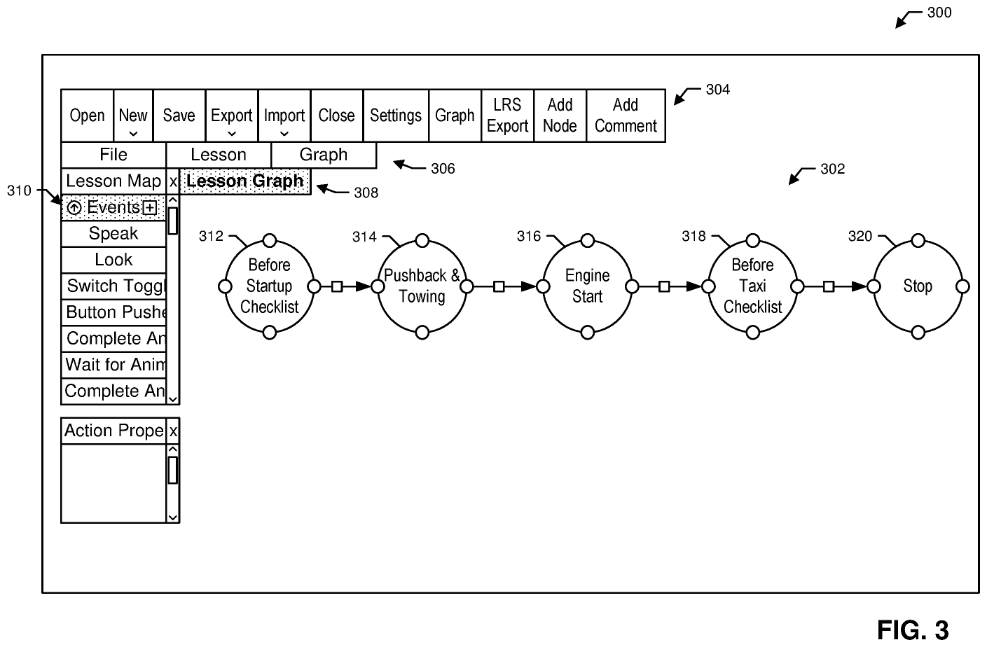

During operation, the instruction authoring tool 120 obtains (e.g., receives or accesses) the lesson description document 102, and a parser 124 of the instruction authoring tool 120 parses the lesson description document 102 to generate a simulation data model 126. The simulation data model 126 is a data model or data structure that identifies a plurality of events to be simulated and a sequence 128 of the plurality of simulation events. The simulation data model 126 also includes identifiers 130 of simulation output files 158 to support the simulation scenario 152. FIGS. 3-6 illustrate graphical representations of various aspects of simulation data models 126. In a particular implementation, the simulation data model 126 is in a format that corresponds to or includes an input format of the code mapping and data linking instructions 142 such that the code mapping and data linking instructions 142 can generate the executable code 144 based on the simulation data model 126.

In some implementations, the instruction authoring tool 120 also includes the graphical editing instructions 136. The graphical editing instructions 136 are executable to generate a display including a graphical representation 138 of the simulation data model 126. For example, the graphical editing instructions 136 represent the simulation data model 126 as a set of nodes (corresponding to event handlers) and interconnections therebetween (representing the sequence of events or branching based on events). The event handlers can include simulation event handlers (to present simulation output), input event handlers (to capture input from a student interacting with the simulation scenario 152), or both. A user 132, such as an instructor or lesson planner, can provide input 134 via the graphical editing instructions 136 to modify (e.g., edit or further refine) the simulation data model 126. To illustrate, the user 132 can change one of the identifiers 130 to point to a different one of the simulation output files 158. As another example, the user 132 can modify the sequence 128 of simulation events or modify other parameters. The other parameters are set based on the lesson description document 102, such as the event descriptors 106, the learning objectives 108, the evaluation criteria 110, the hints 112, etc.

The code mapping and data linking instructions 142 generate the executable code 144 based on the simulation data model 126. For example, the code mapping and data linking instructions 142 map each node (e.g., each event handler) of the simulation data model 126 to an executable code segment 146. In this example, one or more of the code segments 146 point to or incorporate code corresponding to one or more of the simulation output files 158. One or more other code segments 146 include instructions to listen for events from the student 154, such as voice input, manipulation of the simulation input device, eye tracking input, etc. The code mapping and data linking instructions 142 can also set one or more parameter values 148 of the executable code 144 based on the simulation data model 126. For example, one of the parameter values 148 can be set based on the evaluation criterion 110. To illustrate, if the evaluation criterion 110 sets a time limit for the student 154 to perform a particular action, the parameter values 148 based on the evaluation criterion 110 can specify the particular action that is to be performed and the time limit. As a specific example, if the evaluation criterion 110 indicates that the student 154 should toggle a switch of the simulation device 150 within 10 seconds, the parameter values 148 can include an identifier or pointer to input representing the state of the switch, an expected value of the state of the switch after the switch is toggled, and a 10 second time limit. In some implementations, one or more of the parameter values 148 is set based on the hints 112. For example, the hints 112 can indicate an action to be simulated to provide a hint to the student 154 and a condition for providing the hint. To illustrate, the hint can be provided if the student 154 takes too long to perform the correct action, if the student 154 requests assistance, or if the student performs an out of sequence or incorrect action.

The executable code 144 can be stored for future use, or transmitted to the simulation device 150 (e.g., for testing or use). The simulation device 150 executes the executable code to generate the simulation scenario 152. As a specific example, the simulation scenario includes a plurality of simulated events that are arranged to teach the student 154 a new skill or to enable the student to practice a skill. To generate the simulation scenario 152, the simulation device 150 provides output (e.g., audio, visual, or haptic output) based on the simulation output files 158, the executable code 144, or both, and receives input based on the student's action. The input can be in the form of speech, video detection of student actions, manipulation of controls or input devices associated with the simulation device 150, etc.

The instruction authoring tool 120 provides a technical solution to the technical problem of generating executable code for training simulation scenarios. For example, the lesson description document 102 can be generated by a user with no particular programming skills. In some implementations, the lesson description documents 102 uses a relatively common lesson planning format (e.g., the table 104) which enables instructors and lesson planners to use familiar processes to generate and/or review and revise the lesson description document 102. As a result, higher quality and lower cost training material can be generated than by using traditional methods that entail a lesson planner working with a software developer though multiple iterations to generate a simulation scenario.

As one specific use case example, the system 100 can be used to simplify generation of software used during simulation-based training to train pilots how to perform certain procedures defined in a Flight Crew Operations Manual (FCOM). In this example, the simulation device 150 includes a mockup of an aircraft cockpit, the student 154 is a student pilot, and the simulation output files 158 simulate operations of the aircraft, other aircraft crewmembers, ground personnel, or combinations thereof. During training, the executable code 144 controls certain operations of the simulation device 150, such as generating simulated indicator readings and selecting and playing back particular simulation output files 158.

In this example, to generate the executable code 144, an instructional designer (e.g., corresponding to the user 132) creates the lesson description document 102 based on a particular procedure or a portion of a procedure defined in the FCOM, such as a preliminary preflight procedure, a before taxi procedure etc. The instructional designer imports the lesson description document 102 into the instruction authoring tool to create the simulation data model 126, which the instructional designer can edit with the instruction authoring tool 120 if needed. When the instructional designer is satisfied with the simulation data model 126, the instructional designer causes the instruction authoring tool 120 to generate the executable code 144, which is pushed to or made accessible to the simulation device 150.

The student 154 can then enter the simulated cockpit environment and start running through the lesson by executing the executable code 144. As the student 154 interacts with the simulated cockpit, the interactions are evaluated by the executable code 144. The executable code 144 determines, based on the interactions, whether to provide the student 154 with feedback or hints, and which feedback or hints are to be provided. To illustrate, the feedback and hints can be provided by highlighting different parts of the simulated cockpit, pointing to part of the simulated cockpit with an indicator, playing a simulation output file 158 that includes audio or video (e.g., an animation of a virtual pilot), etc. The feedback and hints can be simple and generic, such as playing a simulated output filed 158 that provides audio such as “That action is incorrect,” or the feedback and hints can be more specific, such as playing a simulated output filed 158 that provides audio such as “Turn the IRS Mode Selector to OFF then NAV”.

The student 154 can interact with the simulation scenario 152 by moving simulated controls (e.g., switches, dials, etc.), by demonstrating observation of particular instruments or settings (e.g., based on eye tracking) or by speaking (e.g., reading out an instrument reading, confirming performance of a checklist item, communicating with a simulated actor, or combinations thereof). In some situations, the simulation scenario 152 also interacts with the student 154. To illustrate, a simulated pilot may instruct the student 154 to perform a checklist step, which the student 154 can then perform or confirm as appropriate. The executable code 144 evaluates the student's performance and provides grading or another indication of whether the student 154 appropriately completed the simulated FCOM procedure.

FIG. 2 is a diagram illustrating aspects of the lesson description document 102 of FIG. 1 according to a particular implementation. In the particular implementation illustrated in FIG. 2, the lesson description document 102 is arranged as a workbook that includes multiple tables 104 or spreadsheets, corresponding to tabs 294A-294C. Each table 104 includes a plurality of columns 290 and a plurality of rows 292 defining cells. Each cell is a data field in which an instruction author can provide relevant information to describe an aspect of the simulation scenario 152.

In FIG. 2, each column 290 includes a header field indicating a type of information to be provided in cells of that column 290, and each row 292 includes a sequence identifier indicating an order of simulated events. For example, in FIG. 2, the columns 290 include a sequence column 202, a simulated actions column 204, an expected actions column 206, an evaluation criteria column 208, a feedback column 210, a hints column 212, an enter-state event column 214, an exit-state event column 216, and a learning objective column 218. In other implementations, the table 104 includes more columns 290, fewer columns 290, or different columns 290. For example, in some implementations, enter-state events, exit-state events, or both, are described in the simulation actions column 204 rather than in separate enter-state event and exit-state event columns 214, 216. As another example, the simulation scenario 152 can be used to evaluate learning objects from multiple groups or agencies. In this example, the lesson description document 102 can include multiple separate learning objective columns 218, e.g., one for each of the multiple groups or agencies.

In FIG. 2, the use of multiple tables 104 (each associated with one of the tabs 294) enables a lesson developer to focus on a single aspect of the simulation scenario 152 at a time. For example, when the simulation scenario 152 relates to a series of procedures, each procedure can be associated with a different table 104. Additionally, breaking an aspect of the simulation scenario 152 out into different tables 104 simplifies modular reuse of portions of the simulation scenario 152. For example, simulation scenarios can be used to train response to different emergency scenarios. In this example, emergency scenarios can be injected into the simulation scenario 152 at different times to train different responses. To facilitate generation of such simulation scenarios 152, tables 104 describing typical (e.g., non-emergency) conditions and scenarios can be reused and intermixed with tables 104 describing atypical conditions and scenarios. To illustrate, in FIG. 2, the first tab 294A is shown and is associated with a first activity designated by a first activity identifier 270A (“Activity_ID” in FIG. 2), and the first tab 294A is followed by a second tab 294B associated with a second activity designated by a second activity identifier 270B and a third tab 294C associated with a third activity designated by a third activity identifier 270C. A simulation scenario 152 generated based on the lesson description document 102 of FIG. 2 would include simulations of the first activity, the second activity, and the third activity. To generate a different simulation scenario 152, the lesson developer could interject a fourth tab before, between, or after, the tabs 294A-294C of FIG. 2 (e.g., using copy and paste operations).

In FIG. 2, the sequence column 202 includes sequence identifiers (e.g., “1”, “2”, “n”, where “n” is a placeholder representing any positive integer) indicating an order in which events described in each row are to be simulated. In FIG. 2, the sequence identifiers are sequential numbers; however, in other implementations other sequence identifiers may be used. Further, in some implementations, the sequence identifiers are not arranged sequentially in the rows 292. For example, the sequence identifier “2” can be in a row before the sequence identifier “1”. In this example, the parser 124 of the instruction authoring tool 120 will automatically interpret the sequence identifiers to place events associated with sequence identifier “2” after events associated with sequence identifier “1”.

In FIG. 2, the simulated actions column 204 includes descriptions of a plurality of simulated actions 220 (e.g., simulated actions 220A, 220B and 220N). Each simulated action 220 describes a simulated actor event 222, a simulated equipment event 224, a simulated dialog 226, or a combination thereof. As an example, the simulated dialog 226 can be specified as text in the simulated action 220A. In this example, the text can be converted to output sound (using a text-to-speech process) by the instruction authoring tool 120 to generate an output audio file as part of the executable code 144 or the simulation output files 158. In another example, a cell of the simulated actions column 204 can describe a simulated action 220 by pointing to one of the simulation output files 158. To illustrate, a simulation output file 158 can include a video or animation showing an actor or equipment performing some operations and the video or animation can be inserted into the simulation scenario 152 by pointing to the simulation output file 158 in a cell of the simulated actions column 204.

In FIG. 2, the expected actions column 206 includes descriptions of a plurality of expected actions 230 (e.g., expected actions 230A, 230B and 230N). Each expected action 230 describes one or more of an acceptable action 232 or an unacceptable action 234 that the student 154 may perform. Examples of unacceptable actions 234 include out-of-sequence actions (e.g., an action that should be performed earlier or later in the simulation scenario 152) and incorrect actions. An acceptable action 232 is a proper response to events in the simulation scenario 152.

In FIG. 2, the evaluation criteria column 208 includes descriptions of a plurality of evaluation criteria 240 (e.g., evaluation criteria 240A, 240B and 240N). In some implementations, the evaluation criteria 240 include one or more criteria per expected action 230. In FIG. 2, the evaluation criteria 240A include a timing criterion 242 and one or more event criteria 244. The timing criterion 242 specifies an evaluation result based on how long it takes the student 154 to perform an acceptable action 232 (or another action indicated by the event criteria 244). As an example, the expected action 230A may indicate that the student 154 is expected to toggle a particular switch. In this example, the evaluation criteria 240A can specify a grade or other evaluation criteria that is to be assigned to the student's actions based on how long it takes for the student 154 to toggle the switch. Other evaluation criteria 240 can be based on whether the student 154 performed an action in the expected order, whether a hint was provided before the student 154 performed an acceptable action 232, etc.

In FIG. 2, the feedback column 210 includes descriptions of feedback to be provided based on various actions performed by the student 154. In the example illustrated in FIG. 2, the feedback is provided by outputting the content of one or more file specified by file identifiers 250 (“file_ID” in FIG. 2). In some implementations, multiple file identifiers 250 can be specified per row 292, such as a file identifier for feedback to be provided if the student 154 performs an acceptable action 232 and another file identifier for feedback to be provided if the student 154 performs an unacceptable action 234. In some implementations, multiple feedback columns 210 are included in the table 104, such as a feedback column for feedback to be provided if the student 154 performs an acceptable action 232 and a feedback column for feedback to be provided if the student 154 performs an unacceptable action 234. Where more than one type of unacceptable action 234 is specified (e.g., to distinguish a wrong action from an out of sequence action) each type of unacceptable action 234 can be associated with a respective feedback column.

In FIG. 2, the hints column 212 includes descriptions of a plurality of hints 252 that can be provided to the student 154 (e.g., hints 252A, 252B and 252N). Each hint 252 can include a user interface change 254 (“UI change” in FIG. 2), outputting a file specified by a file identifier 256, or both. Each hint 252 also indicates hint criteria specifying a condition for providing the hint 252 to the student 154. In some implementations, some rows 292 of the table 104 are associated with two or more hints 252. To illustrate, a row 292 can be associated with a first hint that is to be provided when a first hint criterion is satisfied and a second hint that is to be provided if a second hint criterion is satisfied. To illustrate, the first hint can be presented if the student 154 has not performed an acceptable action 232 after 10 seconds and the second hint can be presented if the student 154 has not performed an acceptable action 232 after 20 seconds. As a specific example, the first hint can include highlighting a switch on a control panel that the student 154 is expected to toggle. In this example, the switch is highlighted (an example of a user interface change 254) if the student 154 takes too long (e.g., more than 10 seconds) to toggle the switch. Continuing this example, if the student 154 takes too long (e.g., more than an additional 10 seconds) to toggle the highlighted switch, a simulated actor may prompt the student 154 by asking if the switch is toggled (an example of outputting a file specified by the file identifier 256).

In FIG. 2, the enter-state event column 214 includes descriptions of file identifiers 260 (e.g., file identifiers 260A, 260B and 260N) of simulation output files 158 to be output when transitioning to a particular portion of a sequence of events (e.g., when beginning simulation of a particular event associated with a row 292). Similarly, the exit-state event column 216 includes descriptions of file identifiers 260 (e.g., file identifiers 262A, 262B and 262N) of simulation output files 158 to be output when transitioning from a particular portion of a sequence of events (e.g., when ending simulation of the particular event associated with the row 292). In some implementations, enter-state events, exit-state events, or both, are specified in the simulated actions column 204.

In FIG. 2, the learning objectives column 218 includes descriptions of a learning objectives (objective identifiers 264A, 264B and 264N in FIG. 2) for students or other users of the simulation scenario 152. Specifying the learning objective(s) of each simulation event can help the lesson developer to ensure that the goals of the lesson are completely covered by the subject matters specified in the lesson description document 102. Additionally, in combination with the evaluation criteria 240, the learning objectives can be used to identify remedial training that a student 154 may need or to determine whether a student 154 satisfies specified performance standards.

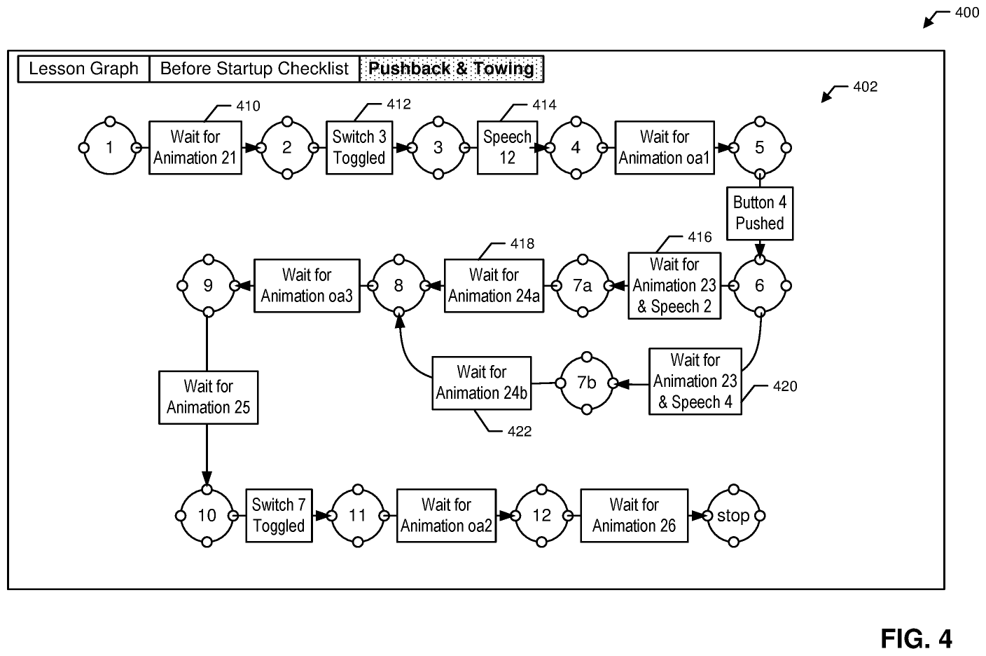

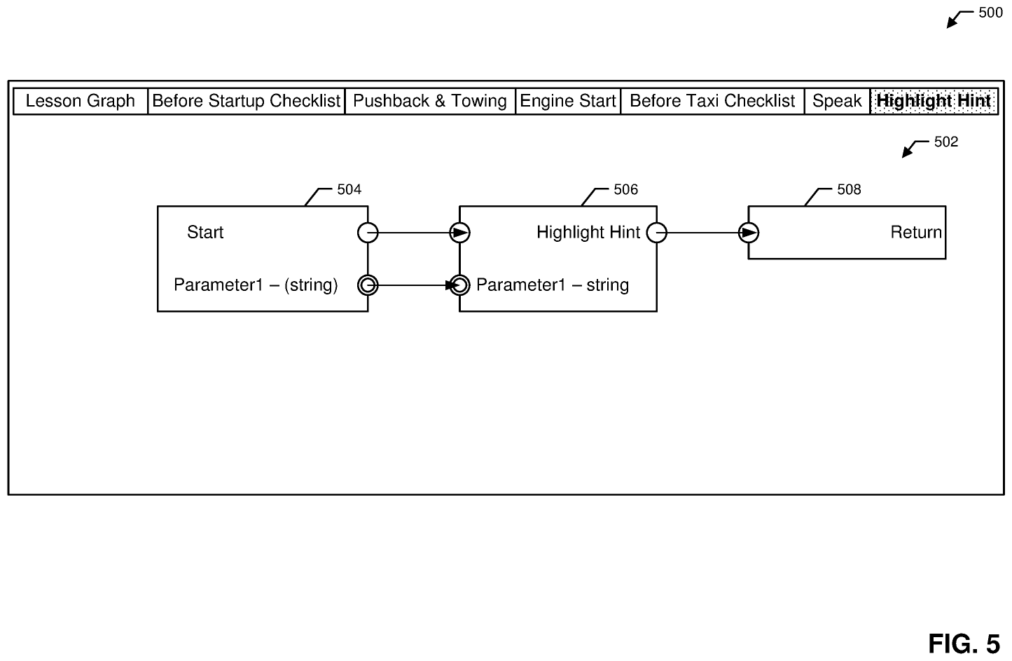

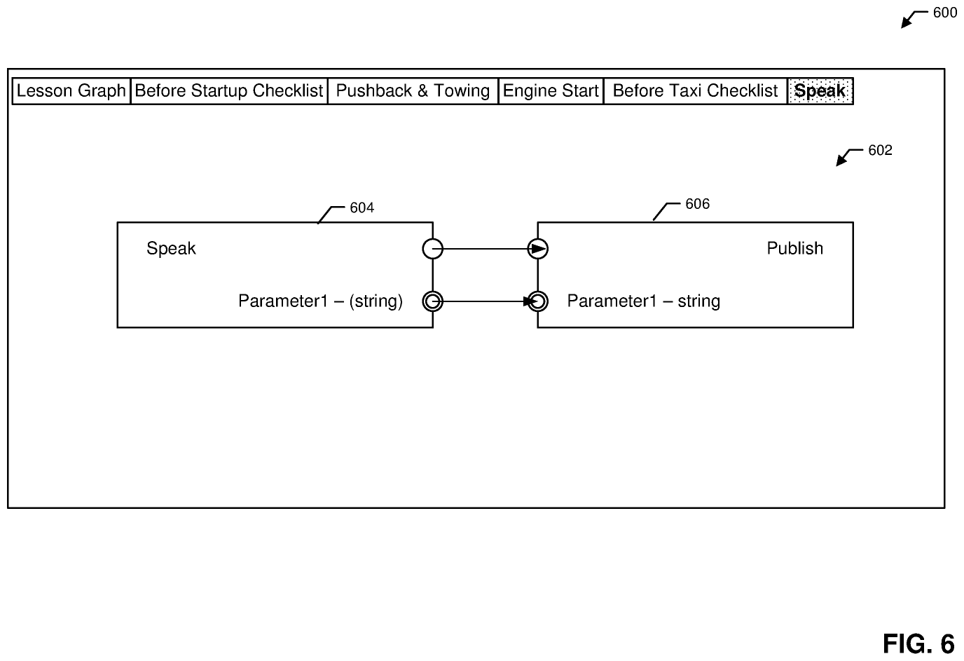

FIGS. 3-6 are diagrams illustrating various display screen that include different aspects of a graphical representation 138 of a simulation data model 126 produced by the instruction authoring tool 120 of FIG. 1. In particular, FIG. 3 and FIG. 4 illustrate lesson graphs, and FIGS. 5-6 illustrate event graphs. In a particular implementation, the simulation data model 126 represented by the graphical representations in FIGS. 3-6 are generated from a lesson description document 102, such as the lesson description document 102 of FIGS. 1 and 2 and displayed by the graphical editing instructions 136.

FIG. 3 illustrates a first graphical user interface 300 that depicts a lesson graph 302 for a simulation scenario 152 of a lesson directed to aircraft ground operations. The lesson graph 302 includes a plurality of nodes and connections therebetween. In FIG. 3, each node represents a particular module or stage in the lesson and the connections represent an order or sequence of the modules or stages of the lesson. For example, in FIG. 3, the nodes include a “before startup checklist” node 312, a “pushback and towing” node 314, an “engine start” node 316, a “before taxi checklist” node 318, and a stop node 320. In this example, the nodes 312-318 correspond to discrete stages during ground operations of an aircraft, and the stop node 320 signals an end of the lesson. In a particular implementation, each the nodes 312-318 corresponds to a tab 294 of the lesson description document 102, and the order of the nodes 312-318 is based on the order of the tabs 294 in the lesson description document 102. In this implementation, the order of the nodes 312-318 in the graph 302 can be changed by modifying the order of the tabs 294 of the lesson description document 102 and causing the instruction authoring tool 120 to process the modified lesson description document 102. Alternatively, the order of the nodes 312-318 can be modified by the graphical editing instructions 136 within the first graphical user interface 300 by dragging and dropping the nodes 312-318. Similarly, a node can be added to or removed from the lesson by adding or removing a tab in the lesson description document 102 or by adding or removing a node in the graph 302.

The first graphical user interface 300 includes a toolbar 304 and various navigation controls 306, 308, 310. The toolbar 304 includes selectable options to access, generate, save, export, or import lesson graphs, as well as selectable options to modify the displayed graph 302, such as be adding a node or a comment. The navigation controls 306-310 facilitate changing among various views of the lesson and related information. Graphical user interfaces 400-600 of FIGS. 4-6, respectively, do not show the toolbar 304 and many of the navigation controls 306-310; however, in some implementations, the graphical user interfaces 400-600 include the same or similar toolbars and/or navigation controls as those illustrated in FIG. 3.

FIG. 4 illustrates a second graphical user interface 400 that depicts a lesson graph 402 for a simulation scenario 152 of a lesson directed to pushback and towing operations of the aircraft ground operations of the lesson graph 302 of FIG. 3. For example, the lesson graph 402 can be displayed responsive to selection of the pushback and towing node 314 of FIG. 3. In a particular implementation, the lesson graph 402 corresponds to and is generated based on a single tab 294 of the lesson description document 102 of FIGS. 1 and 2.

The lesson graph 402 includes a plurality of nodes (represented as circles) and connections therebetween. In FIG. 4, each node of the lesson graph 402 represents a state of the simulation and the connections indicate a sequence in which the states occur. The simulation transitions between states responsive to occurrence of one or more events (represented by rectangles in the lesson graph). Each event of the lesson graph 402 is associated with an event graph, such as the event graph 602 of FIG. 6.

For example, the lesson graph 402 illustrates a wait event 410 between node 1 and node 2, an input event (e.g., a switch toggle event 412) between node 2 and node 3, and another input event (e.g., a speech detection event 414) between node 3 and node 4. In this example, the wait event 410 indicates that the simulation scenario 152 is to transition from a first state (associated with node 1) to a second state (associated with node 2) after a particular simulation output file (identified as “Animation 21”) is output. Continuing this example, the simulation scenario 152 is to remain in the second state until user input is received to toggle a particular switch (identified as “Switch 3”), then the simulation scenario 152 transitions to the third state. Similarly. in this example, the simulation scenario 152 is to remain in the third state until particular speech input (identified as “Speech 12”) is received from the user, then the simulation scenario 152 transitions to a fourth state. In this example, the input events are denoted by identifiers (e.g., Switch 3 and Speech 12) that point to particular expected values. To illustrate, the identifier “Switch 3” indicates that a particular simulated switch is to be actuated and an expected position of the switch after actuation. As another illustration, the identifier “Speech 12” indicates a particular word or phrase that the user is expected to speak.

In some circumstances, several responses can be acceptable when the simulation scenario 152 is in a particular state. The lesson graph 402 illustrates this circumstance between node 6 and node 8. For example, when the simulation scenario 152 is in the state associated with node 6, the simulation output file 158 identified as “Animation 23” is output (as indicated by events 416 and 420). The student 154 can then provide speech input corresponding to “Speech 2” to transition to the state associated with node 7a, or the student 154 can provide speech input corresponding to “Speech 4” to transition to the state associated with node 7b. The transition from the state associated with node 7a to the state associated with node 8 occurs after the simulation output file 158 identified as “Animation 24a” is output, as indicated by the event 418. Similarly, the transition from the state associated with node 7b to the state associated with node 8 occurs after the simulation output file 158 identified as “Animation 24b” is output as indicated by the event 422. Thus, at the state associated with node 6, there are two acceptable student actions—proving speech input corresponding to “Speech 2” or proving speech input corresponding to “Speech 4”—and the simulation scenario 152 is different depending on which acceptable student action is performed.

In some situations, more than one event should occur before the simulation scenario 152 transitions between states. For example, event 416 indicates that the transition from node 6 to node 7a occurs after the simulation output file 158 identified as “Animation 23” is output and after the speech input corresponding to “Speech 2” is provided. Other lesson graphs may require two or more input events (e.g., both speech and toggling a switch) to occur to transition between nodes. Additionally, or in the alternative, some lesson graphs may require that two or more simulation output files 158 be output to transition between nodes.

In a particular implementation, the instruction authoring tool 120 generates each node of the lesson graph 402 based on a row 292 of a tab 294 of the lesson description document 102. In some implementations, the lesson graph 402 can be changed by modifying the order of the rows 292 of the tab 294 of the lesson description document 102 and causing the instruction authoring tool 120 to process the modified lesson description document 102. Alternatively, the order of the nodes of the lesson graph 402 can be modified by the graphical editing instructions 136 within the second graphical user interface 400 by dragging and dropping the nodes.

The nodes of the lesson graph 402 specify data that is used by the code mapping and data linking instructions 142 to generate the executable code 144. For example, each node of the lesson graph 402 corresponds to one or more code segments 146 and corresponding parameter values 148. The nodes of a particular lesson graph 402 specify one or more of a hint wait time, a hint function or event, an initial state of the simulation scenario 152, a grading criteria and calculations, one or more events (e.g., an enter-state event, an exit-state event, an incorrect student action event, an out of sequence student action event, or another event). In some implementations, a node of the lesson graph 402 can represent multiple sub-nodes (e.g., a sub-graph).

FIG. 5 illustrates a third graphical user interface 500 that depicts a function graph 502. Function graphs are used to specify commands to instruct the simulation device 150 to perform some action (e.g., to provide simulation output) of the simulation scenario 152. For example, the function graph 502 of FIG. 5 is for a hint event of the simulation scenario 152. In particular implementations, the instruction authoring tool 120 generates the function graph 502 based on a hint cell of the hints column 212 of a particular row 292 of the lesson description document 102.

In the function graph 502, a first box 504 defines initialization of the function. To illustrate, the function graph 502 is initialized as requiring a single parameter “Parameter1”. Other functions can use multiple parameters or no parameter. A second box 506 of the function graph 502 indicates that a particular command (e.g., a “Highlight Hint” command in FIG. 5) is to be sent to the simulation device 150 with the Parameter1 parameter value that was passed in when the function graph 502 was called. A third box 508 indicates the end of the function graph 502.

The function specified by the function graph 502 can be called when the simulation scenario 152 is in a particular state. To illustrate, the function graph 502 can be linked to, or included within, one of the nodes of the lesson graph 402 of FIG. 4. For example, since the function graph 502 defines a highlight hint function, if the function graph 502 is linked to node 9 of the lesson graph 402, a highlight hint can be generated when the simulation scenario is in a state associated with node 9.

In a particular implementation, the parser 124 detects that a hint cell of the hints column 212 of a particular row 292 of the lesson description document 102 describes a highlight hint function with a single parameter. The parser 124 determines whether a function graph has already been created to send highlight hints with a single parameter to the simulation. If the function graph has not already been generated, the parser 124 or the graphical editing instructions 136 generate the function graph. When the function graph exists, the parameter value associated with the function graph is read from the hint cell and stored as the parameter value of the function graph. The function graph is linked to the state node in the lesson graph 402 that is associated with the particular row 292 of the lesson description document 102.

FIG. 6 illustrates a fourth graphical user interface 600 that depicts an event graph 602. Event graphs are used to specify event handler instructions for the simulation device 150. The event graph 602 specifies an example of a speech event of a simulation scenario 152. In particular implementations, the instruction authoring tool 120 generates the event graph 602 based on a simulated action 220 in a cell of the simulated actions column 204 of a particular row 292 of the lesson description document 102.

A first box 604 of the event graph 602 describes an event type (e.g., speak) to be detected, and initializes a parameter to be passed that indicates a value for the event (e.g., Parameter1 in FIG. 6). In the case of a speech event, the parameter value indicates the content of detected speech (e.g., what the student 154 said), which passes as audio data or as a text representation of the speech as determined using a speech-to-text function. A second box 606 of the event graph 602 indicates that the parameter value is to be published to the simulation device 150 for processing (e.g., for comparison by the executable code 144). For example, the executable code 144 can compare the speech content indicated by the parameter value to expected speech content indicated by the lesson description document 102 to determine whether the speech content from the student 154 represents an acceptable action to allow the simulation scenario 152 to advance to a different state.

The event graph 602 is relatively simple to illustrate a single event capture operation; however, other event graphs can be more complex. For example, an event graph can capture parameter values from more than one student input (e.g., both speech and actuating a simulated control), can capture variable values based on the state of the simulation scenario 152; can perform analysis based on the parameter values, the variable values, or both; and can publish output to the executable code 144 responsive to the analysis. As an example, an event graph can capture a parameter value based on an event detected based on the interaction 156 of the student 154 with the simulation scenario 152 and can set a variable value indicating whether a particular simulation output file 158 has already been presented to the student 154. In this example, the information published to the executable code 144 by the event graph depends on or includes both the variable value and the parameter value.

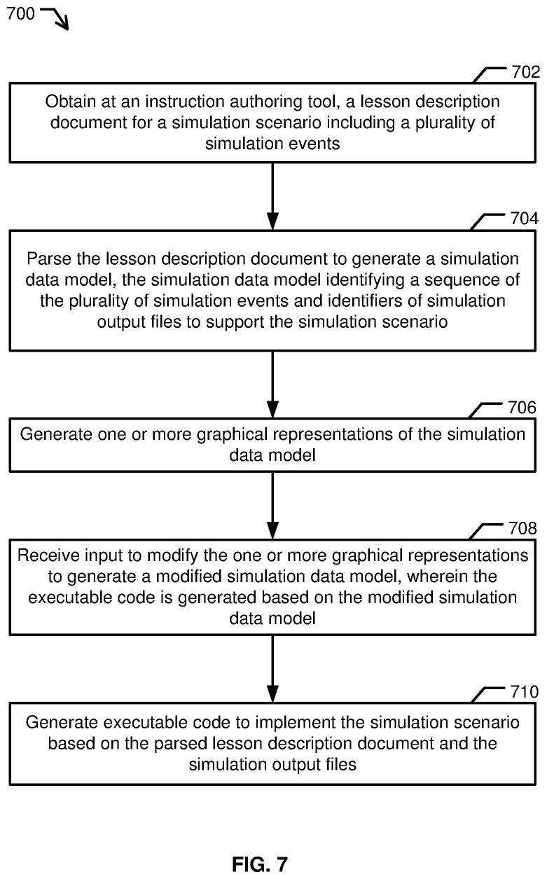

FIG. 7 is a flowchart of a particular implementation of a method 700 of authoring an instructive simulation scenario 152 using the instruction authoring tool 120 of FIG. 1. As an example, the method 700 can be initiated, performed, or controlled by a computing device that includes one or more processors executing instructions from one or more memory devices, such as the computing device 802 of FIG. 8.

The method 700 includes, at 702, obtaining a lesson description document at one or more processors of an instruction authoring tool, where the lesson description document is for a simulation scenario that includes a plurality of simulation events. For example, the instruction authoring tool 120 of FIG. 1 can obtain the lesson description document 102 of FIGS. 1 and 2. In this example, the lesson description document 102 includes a table 104, and cells of the table 104 include event descriptors 106 for events of the simulation scenario 152.

The method 700 includes, at 704, parsing the lesson description document to generate a simulation data model, where the simulation data model identifies a sequence of the plurality of simulation events and identifiers of simulation output files to support the simulation scenario. For example, the parser 124 of the instruction authoring tool 120 generates the simulation data model 126, which indicates the sequence 128 of the simulation events and identifiers 130 of the simulation output files 158 to be used in the simulation scenario 152.

In some implementations, the method 700 also includes, at 706, generating one or more graphical representations of the simulation data model, and at 708, receiving input to modify the one or more graphical representations to generate a modified simulation data model. For example, the graphical editing instructions 136 of the instruction authoring tool 120 of FIG. 1 can generate one or more graphical representations 138, such as one or more of the graphs 302, 402, 502, 602 of FIGS. 3-6, respectively. In this example, a user 132 can provide the input 134 to edit the simulation data model 126 directly in a user interface that displays the graphical representations 138.

The method 700 includes, at 710, generating, by the one or more processors, executable code to implement the simulation scenario based on the simulation data model and the simulation output files. For example, the code mapping and data linking instructions 142 select the code segments 146 and parameter values 148 based on the simulation data model 126. In this example, one or more of the parameter values 148 includes a pointer or data address of one of the simulation output files 158 to enable or cause the simulation device 150 to output content of the one or more simulation output files 158 during execution of the simulation scenario 152.

FIG. 8 is a block diagram of a computing environment 800 including a computing device 802 configured to support aspects of computer-implemented methods and computer-executable program instructions (or code) according to the present disclosure. For example, the computing device 802, or portions thereof, is configured to execute instructions to initiate, perform, or control one or more operations described with reference to FIGS. 1-7. In particular examples, the computing device 802 includes, corresponds to, or is included within the instruction authoring tool 120 of FIG. 1, the simulation device 150 of FIG. 1, or a combination thereof

The computing device 802 includes one or more processors 804. The processor(s) 804 are configured to communicate with system memory 806, one or more storage devices 808, one or more input/output interfaces 810, one or more communications interfaces 812, or any combination thereof. The system memory 806 is a computer-readable storage device and includes volatile memory devices (e.g., random access memory (RAM) devices), nonvolatile memory devices (e.g., read-only memory (ROM) devices, programmable read-only memory, and flash memory), or both. The system memory 806 stores an operating system 814, which may include a basic input/output system for booting the computing device 802 as well as a full operating system to enable the computing device 802 to interact with users, other programs, and other devices. The system memory 806 also stores system (program) data 818, such as the lesson description document 102, the simulation data model 126, the executable code 144, or a combination thereof.

The system memory 806 includes one or more applications 816 (e.g., sets of instructions) executable by the processor(s) 804. As an example, the one or more applications 816 include instructions executable by the processor(s) 804 to initiate, control, or perform one or more operations described with reference to FIGS. 1-7. To illustrate, the one or more applications 816 include instructions executable by the processor(s) 804 to initiate, control, or perform one or more operations described with reference to the instruction authoring tool 120 or the simulation device 150.

The one or more storage devices 808 include nonvolatile storage devices, such as magnetic disks, optical disks, or flash memory devices. In a particular example, the storage devices 808 include both removable and non-removable memory devices. The storage devices 808 are configured to store an operating system, images of operating systems, applications (e.g., one or more of the applications 816), and program data (e.g., the program data 818). In a particular aspect, the system memory 806, the storage devices 808, or both, include tangible (e.g., non-transitory) computer-readable media. In a particular aspect, one or more of the storage devices 808 are external to the computing device 802.

The one or more input/output interfaces 810 enable the computing device 802 to communicate with one or more input/output devices 822 to facilitate user interaction, to communicate with one or more sensors that observe user actions, or both. For example, the one or more input/output interfaces 810 can include a display interface, an input interface, or both. The input/output interface 810 is adapted to receive input (e.g., the input 134 of FIG. 1) from a user, to receive input from another computing device, or a combination thereof. In some implementations, the input/output interface 810 conforms to one or more standard interface protocols, including serial interfaces (e.g., universal serial bus (USB) interfaces or Institute of Electrical and Electronics Engineers (IEEE) interface standards), parallel interfaces, display adapters, audio adapters, or custom interfaces (“IEEE” is a registered trademark of The Institute of Electrical and Electronics Engineers, Inc. of Piscataway, N.J.). In some implementations, the input/output device 822 includes one or more user interface devices and displays, including some combination of buttons, keyboards, pointing devices, displays, speakers, microphones, touch screens, and other devices.

The processor(s) 804 are configured to communicate with devices or controllers 824 via the one or more communications interfaces 812. For example, the one or more communications interfaces 812 can include a network interface. The devices or controllers 824 can include, for example, the simulation device 150 of FIG. 1.

In some implementations, a non-transitory, computer readable medium stores instructions that, when executed by one or more processors, cause the one or more processors to initiate, perform, or control operations to perform part or all of the functionality described above. For example, the instructions may be executable to implement one or more of the operations or methods of FIGS. 1-7. In some implementations, part or all of one or more of the operations or methods of FIGS. 1-7 may be implemented by one or more processors (e.g., one or more central processing units (CPUs), one or more graphics processing units (GPUs), one or more digital signal processors (DSPs)) executing instructions, by dedicated hardware circuitry, or any combination thereof. As a specific example, the instructions may be executable by the processor(s) 804 to cause the processor(s) 804 to perform operations including obtaining a lesson description document for a simulation scenario including a plurality of simulation events; parsing the lesson description document to generate a simulation data model identifying a sequence of the plurality of simulation events and identifiers of simulation output files to support the simulation scenario; and generating executable code to implement the simulation scenario based on the simulation data model and the simulation output files.

Various aspects of the disclosure are described below in a set of interrelated clauses:

According to Clause 1, a method includes obtaining, at one or more processors of an instruction authoring tool, a lesson description document for a simulation scenario that includes a plurality of simulation events; parsing, by the one or more processors, the lesson description document to generate a simulation data model, the simulation data model identifying a sequence of the plurality of simulation events and identifiers of simulation output files to support the simulation scenario; and generating, by the one or more processors, executable code to implement the simulation scenario based on the simulation data model and the simulation output files.

Clause 2 includes the method of Clause 1 wherein one or more simulation events of the plurality of simulation events correspond to an interaction between a student participating in the simulation scenario and at least one of a simulated person, a simulated environment, or a simulated device.

Clause 3 includes the method of Clause 2 wherein, for a particular simulation event of the plurality of simulation events, the lesson description document indicates a hint criterion specifying a condition for providing a hint to the student and one or more hint events to be simulated to provide the hint.

Clause 3 includes the method of Clause 2 wherein the lesson description document indicates a learning objective for the student of a particular simulation event of the plurality of simulation events.

Clause 5 includes the method of Clause 2 wherein the lesson description document indicates an evaluation criterion for determining whether an action of the student is appropriate during a particular simulation event of the plurality of simulation events.

Clause 6 includes the method of Clause 5 wherein the evaluation criterion indicates one or more acceptable actions for the particular simulation event and indicates one or more unacceptable actions for the particular simulation event.

Clause 7 includes the method of Clause 5 wherein the evaluation criterion indicates a time limit for performance of one or more acceptable student actions for the particular simulation event.

Clause 8 includes the method of any of Clauses 1-7 wherein the lesson description document comprises a table including a plurality of cells arranged in rows and columns.

Clause 9 includes the method of Clause 8 wherein an order of the rows of the table represents the sequence of the plurality of simulation events.

Clause 10 includes the method of Clause 8 wherein one or more cells of a particular row include the identifiers of simulation output files for a particular event.

Clause 11 includes the method of Clause 8 wherein one or more cells of a particular row correspond to a simulated equipment event and one or more cells of the particular row correspond to an action of a simulated person.

Clause 12 includes the method of Clause 8 wherein one or more cells of a particular row correspond to an enter-state event that is to be executed at a beginning of simulation of a particular event and one or more cells of the particular row correspond to an exit-state event that is to be executed at an ending of simulation of the particular event.

Clause 13 includes the method of any of Clauses 1-12 wherein generating the executable code comprises mapping first data from the simulation data model to one or more executable code segments and mapping second data from the simulation data model to parameter values of the executable code segments.

Clause 14 includes the method of any of Clauses 1-13 further including generating one or more graphical representations of the simulation data model; and receiving input to modify the one or more graphical representations to generate a modified simulation data model, wherein the executable code is generated based on the modified simulation data model.

According to Clause 15, a computing device includes one or more processors; and one or more memory devices storing instructions that are executable by the one or more processors to cause the one or more processors to initiate, perform, or control operations including receiving, at a processor of an instruction authoring tool, a lesson description document for a simulation scenario including a plurality of simulation events; parsing, by the processor, the lesson description document to generate a simulation data model, the simulation data model identifying a sequence of the plurality of simulation events and identifiers of simulation output files to support the simulation scenario; and determining, by the processor, executable code that implements the simulation scenario based on the simulation data model and the simulation output files.

Clause 16 includes the computing device of Clause 15 wherein the lesson description document comprises a table including a plurality of cells arranged in rows and columns, and wherein the instructions include mapping instructions executable by the one or more processors to map first data from one or more cells of the plurality of cells to one or more executable code segments and to map second data from one or more cells of the plurality of cells to parameter values of the executable code segments.

Clause 17 includes the computing device of Clause 16 wherein the instructions comprise graphical editing instructions executable by the one or more processors to generate one or more graphical representations of the simulation data model; and receive input to modify the one or more graphical representations to generate a modified simulation data model, wherein the executable code is generated based on the modified simulation data model.

Clause 18 includes the computing device of any of Clauses 15-17 further including an interface to send the executable code and one or more of the simulation output files to a simulation device for execution during a simulation scenario.

According to Clause 19, a computer-readable storage device storing instructions that are executable by one or more processors to cause the one or more processors to initiate, perform, or control operations including obtaining a lesson description document for a simulation scenario including a plurality of simulation events; parsing the lesson description document to generate a simulation data model identifying a sequence of the plurality of simulation events and identifiers of simulation output files to support the simulation scenario; and facilitating an implementation of the simulation scenario based on the simulation data model and the simulation output files.

Clause 20 includes the computer-readable storage device of Clause 19 wherein the lesson description document comprises a table including a plurality of cells arranged, in rows and columns, in an order that represents the sequence of the plurality of simulation events and identifies one or more simulated actors, and wherein content of one or more of the cells indicates one or more executable code segments, one or more parameter values of executable code that facilitates the implementation, or both.

The illustrations of the examples described herein are intended to provide a general understanding of the structure of the various implementations. The illustrations are not intended to serve as a complete description of all of the elements and features of apparatus and systems that utilize the structures or methods described herein. Many other implementations may be apparent to those of skill in the art upon reviewing the disclosure. Other implementations may be utilized and derived from the disclosure, such that structural and logical substitutions and changes may be made without departing from the scope of the disclosure. For example, method operations may be performed in a different order than shown in the figures or one or more method operations may be omitted. Accordingly, the disclosure and the figures are to be regarded as illustrative rather than restrictive.

Moreover, although specific examples have been illustrated and described herein, it should be appreciated that any subsequent arrangement designed to achieve the same or similar results may be substituted for the specific implementations shown. This disclosure is intended to cover any and all subsequent adaptations or variations of various implementations. Combinations of the above implementations, and other implementations not specifically described herein, will be apparent to those of skill in the art upon reviewing the description.

The Abstract of the Disclosure is submitted with the understanding that it will not be used to interpret or limit the scope or meaning of the claims. In addition, in the foregoing Detailed Description, various features may be grouped together or described in a single implementation for the purpose of streamlining the disclosure. Examples described above illustrate but do not limit the disclosure. It should also be understood that numerous modifications and variations are possible in accordance with the principles of the present disclosure. As the following claims reflect, the claimed subject matter may be directed to less than all of the features of any of the disclosed examples. Accordingly, the scope of the disclosure is defined by the following claims and their equivalents.

What is claimed is:

1. A method comprising:
obtaining, at one or more processors of an instruction authoring tool, a lesson description document for a simulation scenario that comprises a plurality of simulation events;
parsing, by the one or more processors, the lesson description document to generate a simulation data model, the simulation data model identifying a sequence of the plurality of simulation events and identifiers of simulation output files to support the simulation scenario; and
generating, by the one or more processors, executable code to implement the simulation scenario based on the simulation data model and the simulation output files.

2. The method of claim 1, wherein one or more simulation events of the plurality of simulation events correspond to an interaction between a student participating in the simulation scenario and at least one of a simulated person, a simulated environment, or a simulated device.

3. The method of claim 2, wherein, for a particular simulation event of the plurality of simulation events, the lesson description document indicates a hint criterion specifying a condition for providing a hint to the student and one or more hint events to be simulated to provide the hint.

4. The method of claim 2, wherein the lesson description document indicates a learning objective for the student of a particular simulation event of the plurality of simulation events.

5. The method of claim 2, wherein the lesson description document indicates an evaluation criterion for determining whether an action of the student is appropriate during a particular simulation event of the plurality of simulation events.

6. The method of claim 5, wherein the evaluation criterion indicates one or more acceptable actions for the particular simulation event and indicates one or more unacceptable actions for the particular simulation event.

7. The method of claim 5, wherein the evaluation criterion indicates a time limit for performance of one or more acceptable student actions for the particular simulation event.

8. The method of claim 1, wherein the lesson description document comprises a table including a plurality of cells arranged in rows and columns.

9. The method of claim 8, wherein an order of the rows of the table represents the sequence of the plurality of simulation events.

10. The method of claim 8, wherein one or more cells of a particular row comprise the identifiers of simulation output files for a particular event.

11. The method of claim 8, wherein one or more cells of a particular row correspond to a simulated equipment event and one or more cells of the particular row correspond to an action of a simulated person.

12. The method of claim 8, wherein one or more cells of a particular row correspond to an enter-state event that is to be executed at a beginning of simulation of a particular event and one or more cells of the particular row correspond to an exit-state event that is to be executed at an ending of simulation of the particular event.

13. The method of claim 1, wherein generating the executable code comprises mapping first data from the simulation data model to one or more executable code segments and mapping second data from the simulation data model to parameter values of the executable code segments.

14. The method of claim 1, further comprising:
generating one or more graphical representations of the simulation data model; and
receiving input to modify the one or more graphical representations to generate a modified simulation data model, wherein the executable code is generated based on the modified simulation data model.

15. A computing device comprising:
one or more processors; and
one or more memory devices storing instructions that are executable by the one or more processors to cause the one or more processors to initiate, perform, or control operations comprising:
receiving, at a processor of an instruction authoring tool, a lesson description document for a simulation scenario comprising a plurality of simulation events;
parsing, by the processor, the lesson description document to generate a simulation data model, the simulation data model identifying a sequence of the plurality of simulation events and identifiers of simulation output files to support the simulation scenario; and
determining, by the processor, executable code that implements the simulation scenario based on the simulation data model and the simulation output files.

16. The computing device of claim 15, wherein the lesson description document comprises a table comprising a plurality of cells arranged in rows and columns, and wherein the instructions comprise:
mapping instructions executable by the one or more processors to map first data from one or more cells of the plurality of cells to one or more executable code segments and to map second data from one or more cells of the plurality of cells to parameter values of the executable code segments.

17. The computing device of claim 16, wherein the instructions comprise graphical editing instructions executable by the one or more processors to:
generate one or more graphical representations of the simulation data model; and
receive input to modify the one or more graphical representations to generate a modified simulation data model, wherein the executable code is generated based on the modified simulation data model.

18. The computing device of claim 15, further comprising an interface to send the executable code and one or more of the simulation output files to a simulation device for execution during the simulation scenario.

19. A computer-readable storage device storing instructions that are executable by one or more processors to cause the one or more processors to initiate, perform, or control operations comprising:
obtaining a lesson description document for a simulation scenario comprising a plurality of simulation events;
parsing the lesson description document to generate a simulation data model identifying a sequence of the plurality of simulation events and identifiers of simulation output files to support the simulation scenario; and
facilitating an implementation of the simulation scenario based on the simulation data model and the simulation output files.

20. The computer-readable storage device of claim 19, wherein the lesson description document comprises a table comprising a plurality of cells arranged, in rows and columns, in an order that represents the sequence of the plurality of simulation events and identifies one or more simulated actors, and wherein content of one or more of the cells indicates one or more executable code segments, one or more parameter values of executable code that facilitates the implementation, or both.
